(19) United States
(12) Patent Application Publication
(10) Pub. No.: US 2010/0156318 A1
(43) Pub. Date: Jun. 24, 2010

(54) Light Source System For Use With Medical Devices

(76) Inventor: Felix Quevedo, Palmetto Bay, FL (US)

Correspondence Address: MCHALE & SLAVIN, P.A., 2855 PGA BLVD, PALM BEACH GARDENS, FL, 33410, US

(21) Appl. No.: 12/640,281

(22) Filed: Dec. 17, 2009

Related U.S. Application Data
(60) Provisional application No. 61/138,241, filed on Dec. 17, 2008.

(51) Int. Cl. H05B 37/02; F21L 4/02; G02B 6/04; H01L 33/00

(52) U.S. Cl. 315/294; 362/184; 362/554; 362/555

(57) ABSTRACT

A light source system adapted to embrace the head of the scope of a C-Arm Fluoroscopic machine. The light source system comprises of a cylindrical hollow frame having an outer surface and an inner surface defining an aperture for passage of the head of a scope of a C-Arm Fluoroscopic machine. Retained within the frame is a plurality of light emitting sources which are electrically connected to a power source. The frame consists of two semi-circular portions that are releasably connected by a fastening means for attachment to the head of a scope of a C-Arm Fluoroscopic machine. The light source system further includes a sterile hollow drape connected to the upper face of the frame. The sterile hollow drape is adapted to cover the C-Arm Fluoroscopic machine. The light source system also further includes a transparent grid sheet attached to the lower face of the frame whereby the plurality of light sources reflect a grid pattern projected form the transparent grid sheet.

### CROSS REFERENCE TO RELATED APPLICATIONS

This application claims the benefit under 35 U.S.C. 119(e) of U.S. Provisional Patent Application No. 61/138,241, filed Dec. 17, 2008, entitled, “LIGHT SOURCE SYSTEM FOR USE WITH MEDICAL DEVICES”, the entirety of which is incorporated herein by reference.

### FIELD OF THE INVENTION

This invention relates generally to a light source for medical applications, and more particularly, to a hollow frame having a plurality of light sources retained within and adapted to embrace the head of a C-Arm Fluoroscopic machine.

### BACKGROUND OF THE INVENTION

In the operating room, surgeons should have every possible element working in their favor, ideal lighting is no exception. Therefore, lighting in the operating room should be specifically devised to provide doctors with the best, clearest, and most sterile lighting environment achievable. Because both vision and precision are pivotal in ensuring surgeries unfold as planned, lighting is as important to the success of procedures as the surgical instruments themselves. During surgery, surgeons have so much to consider and the lack of appropriate lighting should not be one of them. For this reason, it is important that the operating room lights provide as much of an advantage to the surgeon as possible.

As discussed above, with most operating procedures adequate lighting is always needed. The operating room is typically equipped with florescent lights which provide general illumination from the ceiling. However, florescent ceiling lights over time become dull and may cause the patient to look discolored, a potentially dangerous situation for an anesthesia provider evaluating a patient. In addition, some ceiling lights may collect dust if they are not recessed. The collection of dust on the ceiling lights creates a non-sterile environment which could possibly lead to infection in the patient should the dust fall within an open wound.

Alternative lighting apparatuses have at times used to provide lighting in inadequate lighting situations. These alternative lighting apparatuses include magnetic, clamp on assemblies, and overhead telescoping apparatuses. For instance, U.S. Pat. No. 3,599,922 discloses an operating room overhead lighting apparatus having a horizontal telescoping arm and a vertical telescoping arm that are interconnected, whereby one of the arms is fixed to the ceiling and the other supports an operating lighting fixture. However, these alternative lighting solutions have their associated disadvantages, such as they are bulky thus interfering and obstructing the very area needing illumination; they are high-voltage thus emitting an immense amount of heat from the source creating an uncomfortable atmosphere for surgeons to operate in; and they must constantly be re-positioned to accommodate different working angles. Furthermore, it would be potentially hazardous to have an alternative light source in an examination or screening room because the threat of microorganisms or other living matter which may attach to the light or associated fixture. These microorganisms or other living matter may contaminate the alternative lighting apparatus and no longer make the room sterile and cause potentially serious consequences to a patient should the microorganisms or other living matter fall into an open wound.

Fluoroscopy is an imaging technique commonly used by physicians to obtain real-time moving images of the internal structures of a patient via the application and detection of penetrating x-rays. The technique transmits x-rays through the patient and converts the x-rays into visible spectrum light by a conversion mechanism (i.e. an x-ray-to-light conversion screen or an x-ray image intensifier). Using the conversion mechanism visible light is captured by a video camera system and displayed on a monitor for use by the physician. Ideally, the technique calls for imaging about the periphery of the patient, and thus spherical angulation is the preferred method. The device used to perform the imaging technique with spherical angulations is a C-Arm Fluoroscopic machine or Fluoroscope. The C-Arm Fluoroscopic machine is commonly used in conjunction with investigative medical measures, orthopedic surgery, angiography, and implantation.

In operating rooms that are equipped with a C-Arm Fluoroscopic machine, the combination of florescent lighting above and no alternative lighting fixtures provide inadequate lighting in the operating room. Although the C-Arm Fluoroscopic machine is technically capable of performing without the use of adequate lighting it is helpful to the physician and the staff to have adequate lighting to position the patient and C-Arm Fluoroscopic machine in the correct orientation and monitor the process. The associated disadvantages with the ceiling lights and alternative lighting apparatuses discussed above do not provide a reasonable solution. Most C-Arm Fluoroscopic machines do not have usable lighting on the equipment, as no known conventional lighting apparatuses or fixtures are practical to adapt to embrace a C-Arm Fluoroscopic machine. What is needed in the art is an unobstructive, hands-free, auxiliary light source adapted to be installed to a C-Arm Fluoroscopic machine.

During surgical operations and other invasive procedures, it is conventional to cover nearby equipment with sterile drapes to prevent microorganisms and other living matter to keep equipment clean and maintain a sterile environment. The use of C-Arm Fluoroscopic machines in surgical procedures presents an opportunity for microorganisms to grow on the machines if proper sterilizing measures are not taken. A sterile drape is needed to protect the machines from blood and other contaminates inherent in surgical operations and to prevent microorganisms from contacting the machine thus possibly infecting the patient. There exist drapes that are sized and shaped specifically to cover a C-Arm Fluoroscopic machine. For instance, U.S. Pat. Nos. 7,108,422 and 5,490,524 disclose a sterile surgical drape which is configured to cover a C-arm machine. While these prior art devices may be suitable for the particular purpose to which they address, these prior art devices would not be suitable for the purposes of the present invention as heretofore described. What is needed in the art is an unobstructive, hands-free, auxiliary light source adapted to embrace the head of a scope of a C-Arm Fluoroscopic machine and used in combination with a sterile drape adapted specifically to cover the C-Arm Fluoroscopic machine. In addition, the auxiliary light source should be adaptable to cooperate with an overhead light source as is typically found in an operating room environment.

### SUMMARY OF THE INVENTION

The objective of this invention is to provide a light source system adapted to embrace the head of the scope of a C-Arm Fluoroscopic machine. The light source system comprises of a cylindrical hollow frame having an outer surface and an inner surface defining an aperture for passage of the head of a scope of a C-Arm Fluoroscopic machine. Retained within the frame is a plurality of light emitting diodes which are electrically connected to a power source. The frame consists of two semi-circular portions that are releasably connected by a fastening means for securement to the head of a scope of a C-Arm Fluoroscopic machine. The light source system may include a sterile hollow drape having a first end attachable to the upper face of the frame and an opposite second end. The sterile hollow drape is constructed and arranged for the passage the scope, head, and foot of the C-arm Fluoroscopic machine. The light source system may also includes a transparent grid sheet attachable to the lower face of the grid, whereby the light sources on the frame reflect a grid image projected from the transparent grid sheet. The grid sheet includes crosshairs and intersecting horizontal and vertical lines.

An alternative embodiment of the light source system further includes a circular disk having an outer periphery frictionally engageable with the aperture on the cylindrical hollow frame having an outer surface and an inner surface defining an aperture for passage of the head of a scope of a C-Arm Fluoroscopic machine. The circular disk includes an opening defined as a hollow sleeve constructed and arranged for passage and securement to a handle on an overhead lighting device typically used in operating rooms. The circular disk also includes a plurality of secondary light emitting diodes electrically connected to a power source to provide a secondary source of lighting.

Accordingly, it is an objective of the present invention to provide a light source system which is unobstructive, hands-free, and is adapted to be installed onto the head of the scope of a C-Arm Fluoroscopic machine.

It is a further objective of the present invention to provide a light source system conveniently attached to the C-Arm Fluoroscopic machine. The light source system include a cylindrical hollow frame having an outer surface and an inner surface defining an aperture for passage of the head of a scope of a C-Arm Fluoroscopic machine, whereby the frame further includes a latching mechanism for easy mounting onto the C-Arm Fluoroscopic machine and dismounting therefrom.

It is a further objective of the present invention to provide a light source system with adequate lighting coming from an angle of the C-Arm Fluoroscopic machine.

It is an additional objective of the present invention to provide a light source system including a circular disk providing additional lighting coming from an angle of the handle of an overhead lighting device.

It is an additional objective of the present invention to provide a surgical drape in combination with the light source which is configured to cover a C-Arm Fluoroscopic machine. The sterile drape prevents microorganisms and other living matter from attaching to the C-Arm Fluoroscopic machine and maintains a sterile environment within the operating room.

It is another objective of the present invention to provide a transparent grid sheet in combination with the light source. The transparent grid sheet is attached to the lower face of the frame of the light source system when embracing the C-Arm Fluoroscopic machine, whereby the light source on the frame reflects the grid pattern onto the subject where the light source is aimed.

It is a another objective of the present invention to provide a light source system that utilizes light emitting diodes to generate an intense light and gives contrast to the depth and relationship of all anatomic structures on the operating room table.

It is a yet another objective of the present invention to provide a light source system equipped with a light intensity control to provide the surgeon with more light if needed.

It is yet another objective of the present invention to provide a light source system having a plurality of light sources to decrease shadows, thereby producing a shadowless beam of light.

It is yet another objective of the present invention to provide a light source system emanating a beam of light producing the blue-white color of daylight, however, not limited to this color spectrum.

It is another additional objective of the present invention to provide a light source system producing less than 25,000 mW/cm² of radiant energy to prevent injury and drying to the exposed bodily tissue on the operating table, and create a comfortable environment for the surgeon operating.

It is another additional objective of the present invention to provide a light source system using fiber-optic cables to produce a cool light and reduce shadows or light emitting diodes which are highly efficient in drawing low voltage.

It is yet another additional objective of the present invention to provide a light source system that may be disposable and inexpensive to produce.

It is yet another additional objective of the present invention to provide a light source system whereby the frame, the emitter, and the head of the C-Arm Fluoroscopic machine are concentric so as to share the same axis.

It is yet another further additional objective of the present invention to provide a light source system having light emitting diodes that produce a wavelength of light suitable to kill bacteria.

It is yet another further additional objective of the present invention to provide a light source system may comprise of a kit for manufacturing.

Other objectives and advantages of this invention will become apparent from the following description taken in conjunction with any accompanying drawings wherein are set forth, by way of illustration and example, certain embodiments of this invention. Any drawings contained herein constitute a part of this specification and include exemplary embodiments of the present invention and illustrate various objects and features thereof.

### BRIEF DESCRIPTION OF THE FIGURES

FIG. 1 is pictorial representation of a prior art C-Arm Fluoroscopic machine;

FIG. 2 is a bottom view of the light source system of the present invention;

FIG. 3 is an isometric view of the light source system of the present invention including a drape mounted on a C-Arm Fluoroscopic machine;

FIG. 4 is an isometric view of an alternative embodiment of the light source system having the circular disk attached to the cylindrical hollow frame mounted on a handle of an overhead lighting device;

FIG. 5 is a bottom view of an alternative embodiment of the light source system for mounting on a handle of an overhead lighting device;

FIG. 6 is a bottom view of the light source of the present invention including a grid sheet; and

FIG. 7 is an alternative embodiment of the present invention.

### DETAILED DESCRIPTION OF THE INVENTION

Detailed embodiments of the instant invention are disclosed herein, however, it is to be understood that the disclosed embodiments are merely exemplary of the invention, which may be embodied in various forms. Therefore, specific functional and structural details disclosed herein are not to be interpreted as limiting, but merely as a basis for the claims and as a representation basis for teaching one skilled in the art to variously employ the present invention in virtually any appropriately detailed structure.

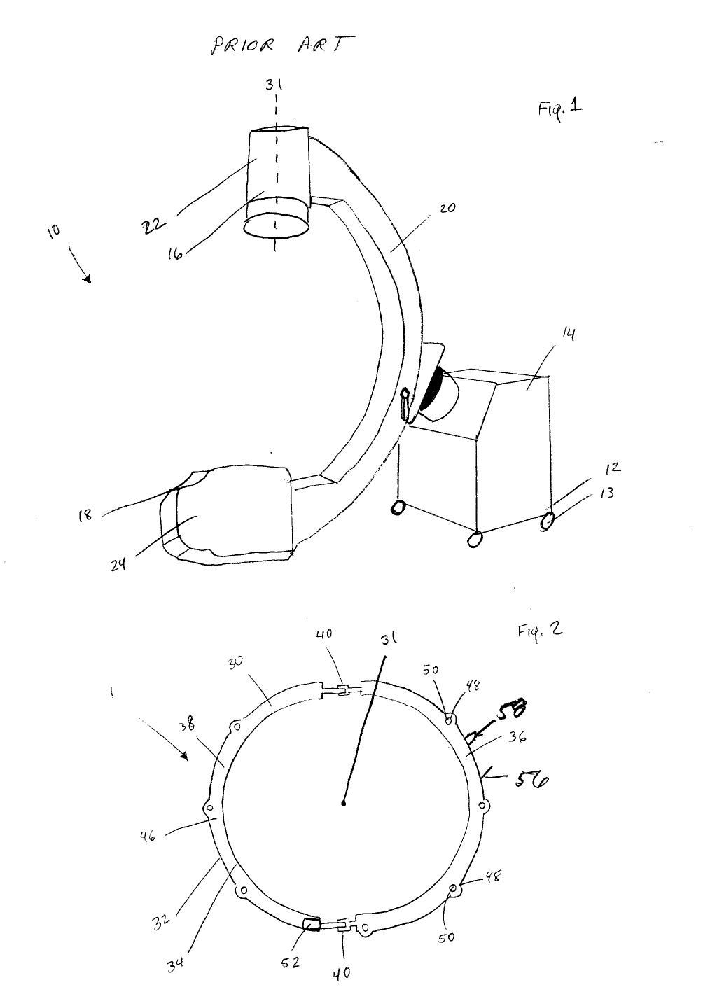

Referring now to FIGS. 1-5, wherein like components are numbered consistently throughout, FIG. 1 illustrates the exemplary representation of a C-Arm Fluoroscopic machine 10. The C-Arm Fluoroscopic machine 10 is supported by a base 12. The base 12 is provided with lockable wheels 13 so that the C-Arm Fluoroscopic machine 10 can be easily moved from one location to another. Attached to the base 12 is a housing 14, the housing 14 houses the necessary electrical equipment. The C-Arm Fluoroscopic machine 10 also includes an emitter 16 and an image intensifier 18. The emitter 16 generates x-rays and the image intensifier 18 is generally configured to received those rays and provide a useable image 19, see FIG. 3. In this particular exemplary representation, the emitter 16 is located in the head 22 at one end of C-arm 20 and the image intensifier 18 is located in the foot 24 at the other end of C-arm 20 of the Fluoroscopic machine 10. However, many C-Arm Fluoroscopic machines exist in the art and the positions of emitter and image intensifier may be reversed.

In FIG. 2 illustrates a preferred embodiment of the light source system 1 of the present invention. The light source system 1 may be manufactured to be disposable. The light source system 1 comprises a hollow frame 30. The hollow frame 30 has an outer surface 32 and an inner surface 34. The inner surface 34 having a diameter sized for the passage of the head 22 of the C-Arm Fluoroscopic machine 10. The frame 30 is constructed of a first half portion 36 and a second half portion 38, each portion 36 and 38 having a semi-circular shape when viewed from the top or the bottom of the frame. The first half portion 36 being releasably connected to the second half portion 38 by fasteners 40 at opposite ends of each portion for attachment of the frame 30 to the head 22 of the scope 20 of the C-Arm Fluoroscopic machine 10. More specifically, the semi-circular inner surface 34 of each portion 36 and 38 is sized to cooperate and frictionally engage the head 22 of the scope 20 of the C-arm Fluoroscopic machine 10 thereby securing the frame 30 onto the head 22. Rubber or similar other materials can optionally be placed on the inner surface 34 of frame 30 to provide additional support of the frame 30 on the head 22. Suitable releasable fasteners 40 are provided to hold the two semi-circular portions 36 and 38 in a closed or C-Arm embracing position. Alternatively, hook and loop type fasteners can be employed in place of the fasteners 40. It is also contemplated that a hinge member may be provided in place of one of the fasteners 40 on one end of the portion and a fastener 40 on the opposite end. This embodiment allows the first and second portions 36 and 38 to be connected at the hinge member to facilitate ease of assembly onto the head 22.

The frame 30 further includes an upper surface 44 (FIG. 3) and a lower surface 46 (FIG. 2). The lower surface 46 being directed toward the operating table, not shown. On the cylindrical hollow frame's lower surface 46 there are provided a plurality of openings 48 from which beams of light from a plurality of light sources 50 emerge and converge at a point or small region on the central axis 31 of the cylindrical hollow frame 30, head 22, and emitter 16. It is contemplated that the light sources can be oscillating spheres for multi-directional light beams so as not to converge on the central axis of the frame and head of the C-Arm Fluoroscopic machine. The plurality of light sources 50 may be fiber-optic cables to produce a cool light and reduce shadows or they can be light emitting diodes which are highly efficient in drawing low voltage. The light sources may have a wavelength that produces a light suitable to kill bacteria. It is also contemplated that the light sources emanate a beam of light producing the blue-white color of daylight, however, the emanating light is not limited to this color spectrum. The inner surface 34 of the frame 30 may be lined with a compressible material such as, but not limited to, rubber for compression with the head 22 of the scope 20 of the C-Arm Fluoroscopic machine 10. The cylindrical hollow frame 10 is preferably constructed of a plastic polymer or other suitable materials. The frame 30 is equipped with a power supply 52 associated thereon the frame 30. Preferably the power supply is a plurality of batteries. However, any other type of power source can be employed, such as alternating current or direct current. The power supply may be located at any suitable location on the device without departing from the scope of the invention. The plurality of light sources 50 are electrically connected by wires, not shown, within the frame 30 to the power source 52. The frame 30 is also provided with an ON/OFF switch 56 and/or a light intensity control 58 to provide the surgeon with the proper amount of light required. An alternative embodiment of the light source system, not shown, includes constructing the light source system of a flexible strip whereby a plurality of light sources are embedded within. The flexible strip comprises of one horizontal piece having opposite ends. The first end being releasably connected to the opposite end to embrace the head of the scope of a C-Arm Fluoroscopic machine 10. The flexible strip is equipped with a power supply associated thereon. The plurality of light sources are electrically connected by wires within the flexible strip to the power source.

A surgical environment is preferably sterile. Thus, most equipment used in this environment must be sterilized or covered with a surgical drape. Obviously, the C-Arm Fluoroscopic machine is too large to place in a sterilizing machine, thus it must be covered with a surgical drape. The integrated sterile drape 60 is shown in FIG. 3. A sterile drape 60 is attached to the upper face 44 of the frame 30 and is adapted to overlay the head 22, scope 20, and foot 24 of the C-Arm Fluoroscopic machine 10. It is also contemplated that the drape 60 may cover the base 12, support housing 14, and operating table (not shown). Several embodiments of the sterile drape are contemplated. The sterile drape 60 comprises of a hollow sleeve 62 having an interior wall 63, exterior wall 64, an open end 66, and an opposite end 68 connected to the upper face 44 of the frame 30. The sterile drape 60 should be constructed of a sufficient length to extend from the head 22 of the scope 20 to the foot 24 of the scope 20. Furthermore, the sterile drape 60 may be provided with additional sterile drape material to attach thereto for covering the base 12, support housing 14, and operating table. The sterile drape 60 may be bisected by an open seam 70, which allows the fabric to be pulled apart in order to slip over the C-Arm machine 10 and into the appropriate position. The open seam 70 is fastened together by a plurality of closures 72. These closures 72 can be buttons, snaps, hooks, VELCRO® (fabric hook and loop fasteners) or many other types of conventional closures. The surgical drape 60 may be constructed of an x-ray transparent material, such as plastic or the like. Alternative embodiments of the sterile drape include constructing the drape of two sheets of material that are joined by their edges into a bag-shaped drape. The drape bag is then placed about the C-Arm Fluoroscopic machine, tie straps are attached to the drape and used to secure the drape to the C-Arm Fluoroscopic machine 10, and one end of the drape bag is secured to the upper face of the frame.

The light source system 1 of the present invention may also be provided with a transparent grid sheet 80, as illustrated in FIG. 6. The transparent grid sheet 80 is secured to the to the lower face 46 of the frame 30 whereby the plurality of light sources 50 on the frame 30 reflects a grid image projected from transparent grid sheet 80. The transparent grid sheet 80 has indicia 84 thereon that may be reflected onto a patient or surface. The frame 30 is positioned about the emitter 16 on the C-Arm Fluoroscopic machine 10 and thus concentric to the central axis 31 of the head 22, the emitter 16, and X-ray beams emitting from the emitter 22. Thus the grid image projected by the plurality of light sources 50 from the transparent grid sheet 80 is centered about the C-Aim Fluoroscopic machine's center axis 31 allowing the surgeon to position the patient in the correct position according to the indicia 84 on the projected grid image.

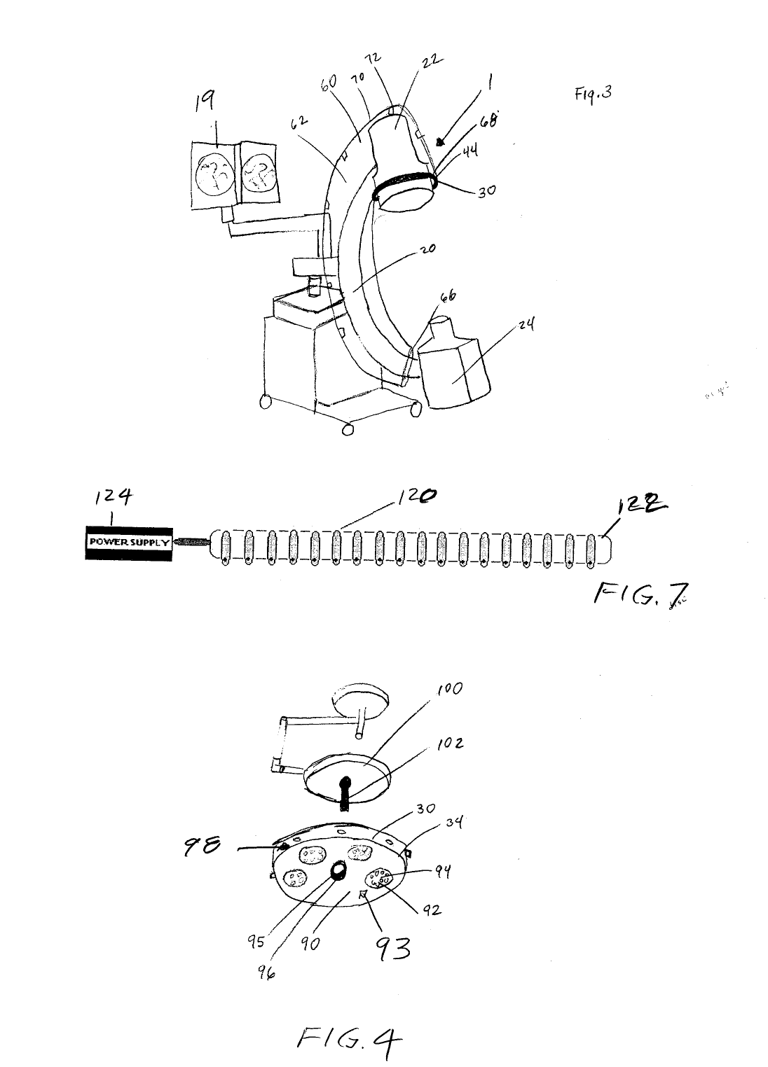

Current overhead lighting devices 100 in operating rooms emit an immense amount of heat ion conjunction with the light that creates a non-sterile and uncomfortable atmosphere for surgeons to operate in. These overhead lighting devices 100 include a handle 102 which permits a surgeon or other person in the operating room to manipulate the light to direct the light where it is most effective. Another embodiment of the present invention is shown in FIG. 4. The light system 1 includes frame 30. A disc 90 is secured within the perimeter of the system 1. The disc 90 is secured to the inner surface 34 of system 1 to be adapted to the handle 102 on an overhead lighting apparatus 100 in an operating room. The disc may frictionally engage with the frame for securement thereto. Alternative embodiments contemplate a slide-in snap adapter, whereby the inner surface of the frame and the outer periphery surface of the disc are equipped with snap-in fasteners. The disc 90 is provided with a plurality of separately and evenly spaced pods 92. Each pod 92 having a plurality of light sources 94 within. The plurality of light sources 94 are electrically connected to a power source 93 housed within the disc 90. The plurality of light sources 94 may be fiber-optic cables to produce a cool light and reduce shadows or light emitting diodes which are highly efficient in drawing low voltage. The light sources 94 may also have a wavelength that produces a light suitable to kill bacteria. It is also contemplated that the light sources 94 emanate a beam of light producing the blue-white color of daylight, however, the emanating light is not limited to this color spectrum. It is contemplated that disc is provided without the pods and the light sources are provided on the outer surface of the disc. At the center 95 of the disc 90 there is a sleeve 96. The sleeve 96 is constructed and arranged fit over and frictionally engage the handle 102 of the overhead lighting device 100 in an operating room and thereby secure the light system 1 to the overhead light 100. The disc 90 is constructed of a plastic polymer or other similar materials. The disc 90 also provided with an ON/OFF switch 98 for operation of the plurality of light sources 94. Other alternative embodiments include the disc 90 being separable from the frame, so as to be secured to a handle on an overhead lighting device without the frame attached to the disc.

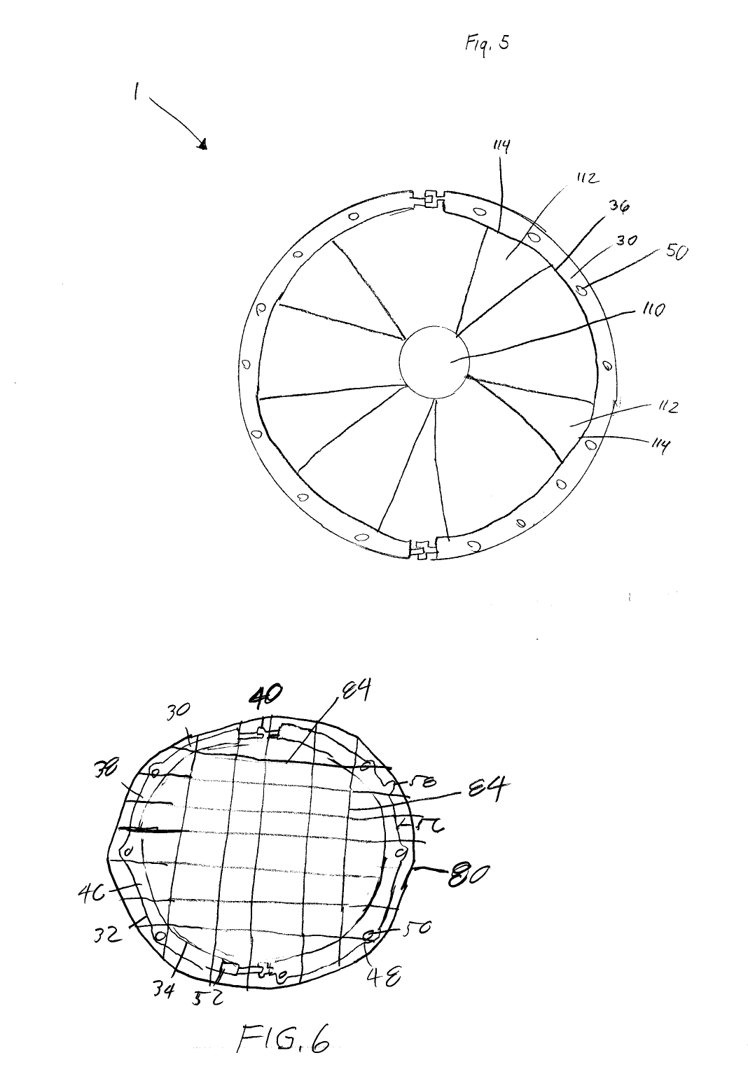

A further embodiment of the light source system 1 is illustrated in FIG. 5. This embodiment includes a hollow mounting handle 110 adapted to receive the handle 102 of an overhead lighting apparatus 100 therein. The hollow mounting handle 110 includes at two arms 112 extending therefrom, to be attached to the inner surface 34 of the frame 30. The arms 112 are constructed and arranged to extend up to the inner surface of the frame 30 for attachment thereto using fasteners 114. Using the plurality of light sources 50 on the frame 30, the alternative embodiment can be fitted onto the handle 102 on an overhead lighting apparatus 100 to provide lighting.

Another embodiment of the present invention is illustrated in FIG. 7. A plurality of individual lights, such as LEDs or sources of light 120, are secured onto a support member 122. A power supply 124 provides electrical power to the lights 120. Preferably two strips of lights encircle the head 22 of the C-Arm Fluoroscopic machine 10. Alternatively, a single strip of lights can be employed.

All patents and publications mentioned in this specification are indicative of the levels of those skilled in the art to which the invention pertains. All patents and publications are herein incorporated by reference to the same extent as if each individual publication was specifically and individually indicated to be incorporated by reference.

It is to be understood that while a certain form of the invention is illustrated, it is not to be limited to the specific form or arrangement herein described and shown. It will be apparent to those skilled in the art that various changes may be made without departing from the scope of the invention and the invention is not to be considered limited to what is shown and described in the specification and any drawings/figures included herein.

One skilled in the art will readily appreciate that the present invention is well adapted to carry out the objectives and obtain the ends and advantages mentioned, as well as those inherent therein. The embodiments, methods, procedures and techniques described herein are presently representative of the preferred embodiments, are intended to be exemplary and are not intended as limitations on the scope. Changes therein and other uses will occur to those skilled in the art which are encompassed within the spirit of the invention and are defined by the scope of the appended claims. Although the invention has been described in connection with specific preferred embodiments, it should be understood that the invention as claimed should not be unduly limited to such specific embodiments. Indeed, various modifications of the described modes for carrying out the invention which are obvious to those skilled in the art are intended to be within the scope of the following claims.

What is claimed is:

1. A source of light for use with C-Arm fluoroscopic machine comprising:
at least two substantially semi-circular frame members;
fasteners secured to each one of said at least two substantially semi-circular frame members, said fasteners being constructed and arranges to releasably secure each of said substantially semi-circular frame members to one another;
a plurality of light sources positioned within each of said frame members; and
a power source electrically connected to each of said lights and providing electrical power to said light sources.

2. The device of claim 1 wherein said power source is located within one of said frame members.

3. The device of claim 1 wherein each said frame member includes an outer surface, an inner surface, a top surface and a bottom surface; said light sources direct light through said bottom surface of each of said frame members.

4. The device of claim 1 wherein said fasteners are hook and loop fasteners.

5. The device of claim 1 wherein said light sources are optical fibers.

6. The device of claim 1 wherein said light sources are light emitting diodes.

7. The device of claim 3 including a grid releasably secured to said bottom surface of each said frame member, said grid including a light transparent material and a light opaque pattern on said light transparent material, said grid spaced from and covering said light sources, whereby light from said light sources passes through said grid and projects said opaque pattern on an object positioned below said device.

8. The device of claim 1 including a control which varies the intensity of the light from said light sources.

9. The device of claim 1 wherein the wavelength of said light from said light sources

10. The device of claim 1 including a handle, said handle positioned proximate a center of an area encompassed by said frame members; a plurality of arms, said arms secured to said frame members and said handle whereby said handle is positioned proximate the center of an are encompassed by said frame members.

11. A source of light comprising:
at least two substantially semi-circular frame members;
fasteners secured to each one of said at least two substantially semi-circular frame members, said fasteners being constructed and arranges to releasably secure each of said substantially semi-circular frame members to one another;
a disc located within and secured to said semi-circular frame members;
a plurality of light sources positioned on said disc; and
a power source electrically connected to each of said lights and providing electrical power to said light sources.

12. The device of claim 11 including a handle, said handle positioned proximate a center of said disc and secured to said disc, whereby said device can be secured to an overhead light.

13. The device of claim 11 wherein each said frame member includes an outer surface, an inner surface, a top surface and a bottom surface; said disc is secured to said inner surfaces of said frame members.

14. The device of claim 11 wherein said light sources are optical fibers.

15. The device of claim 11 wherein said light sources are light emitting diodes.
